(19) United States
(12) Patent Application Publication
(10) Pub. No.: US 2019/0129309 A1
(43) Pub. Date: May 2, 2019

(54) DIRECT EXPOSURE MACHINE WITHOUT MASK

(71) Applicant: SHUZ TUNG MACHINERY INDUSTRIAL CO.,LTD., TAICHUNG CITY (TW)

(72) Inventors: KUO-SHU HUNG, TAICHUNG CITY (TW); CHUN-HSIEN LIU, TAICHUNG CITY (TW); MING-HUNG CHANG, TAICHUNG CITY (TW); SHU-CHENG LIAO, TAICHUNG CITY (TW)

(21) Appl. No.: 16/177,032

(22) Filed: Oct. 31, 2018

(30) Foreign Application Priority Data
Oct. 31, 2017 (TW) 106137625

(51) Int. Cl. G03F 7/20; G02B 26/10; B41C 1/10; G02B 3/10

(52) U.S. Cl. CPC G03F 7/2053; G02B 26/108; G02B 3/02; G02B 3/10; B41C 1/1033

(57) ABSTRACT

The present invention provides a direct exposure machine without mask, comprising a stage device and an exposure device. The stage device supports an exposed substrate, a surface of which coats with a sensitive layer. The exposure device shifts relatively to the stage device and includes a first exposure module. The first exposure module includes a light source, a penetrating scanner and multi-focus lenses. The light source outputs multiple beams arranged parallel to each other. The penetrating scanner includes a multifaceted prism driven to rotate, which has multiple facets. Each beam goes into one facet and out from the other to the sensitive layer of the exposed substrate. The multi-focus lenses are disposed between the light source and the multifaceted prism for focusing the beams to the substrate to be exposed.

### BACKGROUND OF THE INVENTION

### 1. Field of the Invention

The present invention relates to a direct exposure machine without mask.

### 2. Description of the Related Art

The patent application, the patent number WO0230675 A1, discloses a prior direct laser exposure machine, which can form a latent image on a surface of the substrate to be exposed without mask. The direct laser exposure machine has a laser light source and a manifold reflecting mirrors driven to rotate, wherein the manifold reflecting mirrors are disposed between the laser light source and the exposed substrate so as to reflect the laser beam generated by the laser light source to the exposed substrate. As shown in FIG. 11, after laser beam 92 of the direct laser exposure machine mentioned above is reflected by one of the mirrors 91 of the manifold reflecting mirrors 9, the height variation of the exposed substrate will cause the focus points F3, F4 to shift horizontally. Moreover, as shown in FIG. 12, the position of the focus point F will vary due to the variation of the angle of the reflective mirror 91 which causes generated image of the exposed substrate 4 to lose focus.

### SUMMARY OF THE INVENTION

It is an object of the present invention to provide a direct exposure machine without mask, comprising a stage device and an exposure device. The stage device supports an exposed substrate, a surface of which coats with a sensitive layer. The exposure device shifts relatively to the stage device and includes a first exposure module. The first exposure module includes a light source, a penetrating scanner and multi-focus lens. The light source outputs multiple beams arranged parallel to each other. The penetrating scanner includes a multifaceted prism driven to rotate, which has multiple facets. Each beam goes into one facet and out from the other to the sensitive layer of the exposed substrate. The multi-focus lenses are disposed between the light source and the multifaceted prism for focusing the beams to the exposed substrate.

The foregoing and other objectives, features, and advantages of the invention will be more readily understood upon consideration of the following detailed description of the invention, taken in conjunction with the accompanying drawings.

### BRIEF DESCRIPTION OF THE DRAWINGS

FIG. 1 illustrates the spatial structure schematic diagram of the direct exposure machine without mask of the invention;

FIG. 2 is the spatial structure schematic diagram of the laser exposure device of the direct exposure machine without mask in FIG. 1;

FIG. 3 is the partly enlarge schematic diagram of FIG. 2;

FIG. 4 is the top view schematic diagram of the two laser module and the exposed substrate of the laser exposure device in FIG. 2;

FIG. 5 is the spatial structure schematic diagram of one of the laser module of the laser exposure device in FIG. 2;

FIG. 6 is the section structure schematic diagram of the part laser module in FIG. 5;

FIG. 7 is the section schematic diagram sectioned along the VII-VII line in FIG. 6;

FIG. 8A to FIG. 8C show during the process the multi-prism scanner of the invention rotates the laser beams form a strip laser speckle on the exposed substrate;

FIG. 9 shows the schematic diagram of the strip laser speckle formed by the laser exposure device at the X-Y coordinate;

FIG. 10 shows the schematic diagram for the multi-prism scanner of the invention when the laser beam scans and perpendicularly emits into the surface of the exposed substrate;

FIG. 11 shows the schematic diagram of the shifting of the focus point due to the variation of the height of the substrate for the prior multifaceted scanner when the laser beam scans; and

FIG. 12 shows the schematic diagram that the prior mirror causes missing the focus point surrounding the image since the rotating angle of the prior mirror varies when the prior mirror reflects the laser beam.

### DETAILED DESCRIPTION OF EMBODIMENTS

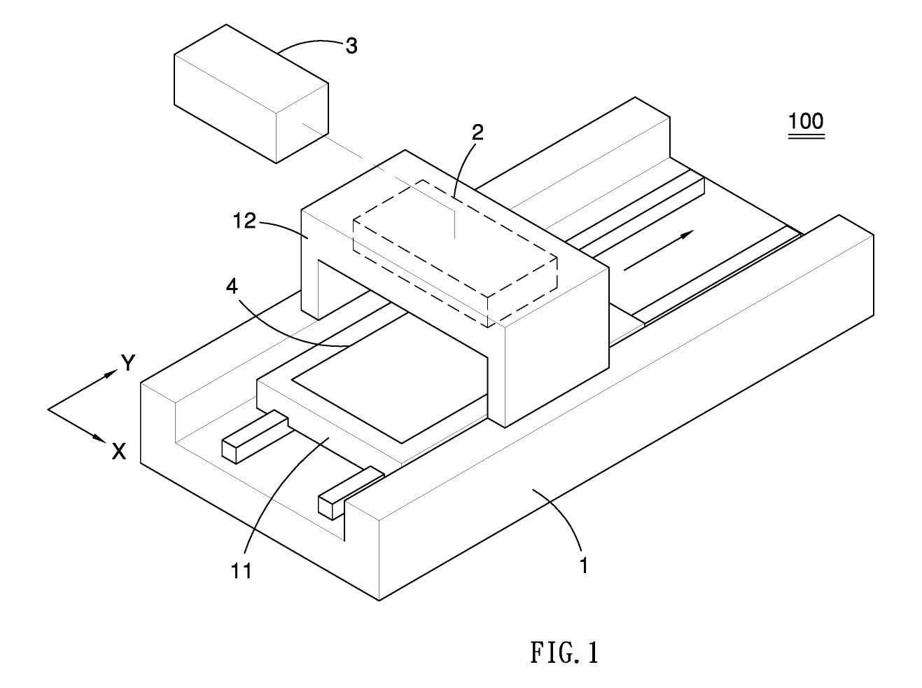

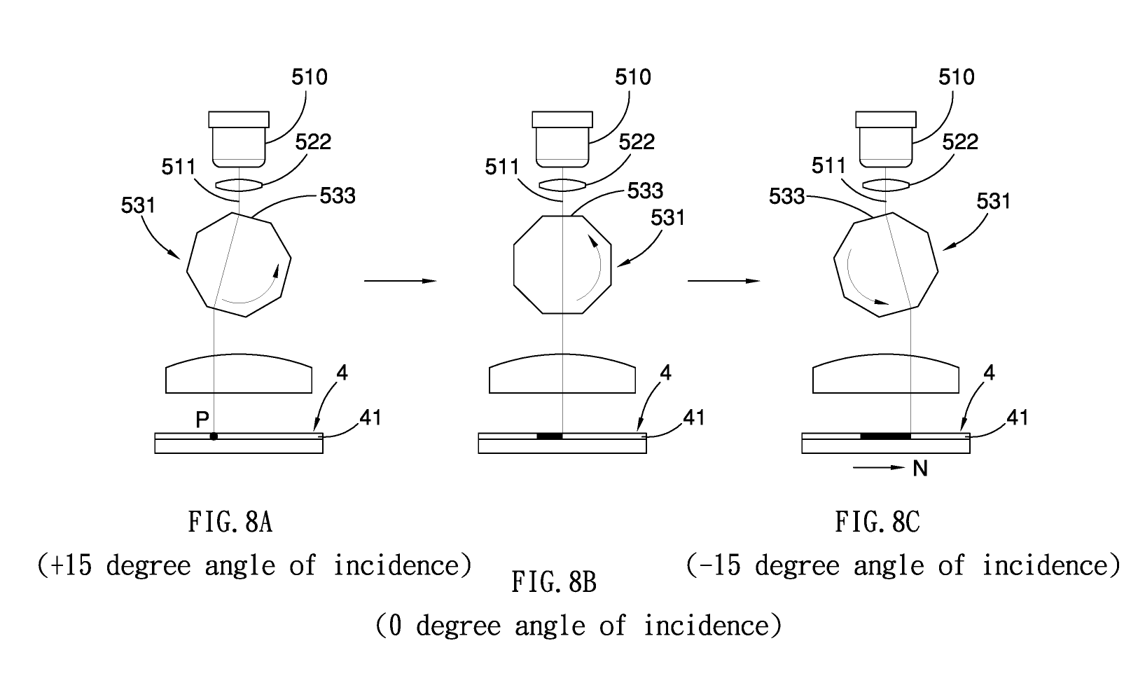

FIG. 1 to FIG. 10 show the preferred embodiments of the direct exposure machine without mask 100 of the invention. The direct exposure machine without mask 100 exposes an exposed substrate 4 to form a latent image on a sensitive layer 41 (refer to FIG. 8) of the exposed substrate 4.

As shown in FIG. 1, the direct exposure machine without mask 100 includes a machine station 1, an exposure device 2 and a control unit 3. The exposure device 2 disposes on a gantry 12 of the machine station 1. The machine station 1 has a stage device 11 for supporting the exposed substrate 4.

In the embodiment, the gantry 12 is static while the stage device 11 delivers the exposed substrate 4 along the Y direction; on the contrary, the stage device 11 is static while the gantry 12 moves along the Y direction. In other words, the stage device 11 and the exposure device 2 on the gantry 12 can relatively shift at the Y direction. Furthermore, when the exposure device 2 shifts relative to the stage device 11, the sensitive layer 41 of the exposed substrate 4 at each position in the X direction can be exposed selectively by the exposure device 2. Therefore, the latent image for two dimension will form on the sensitive layer 41. A corresponding specific pattern of the latent image can be displayed on the exposed substrate 4 by a subsequent developing process.

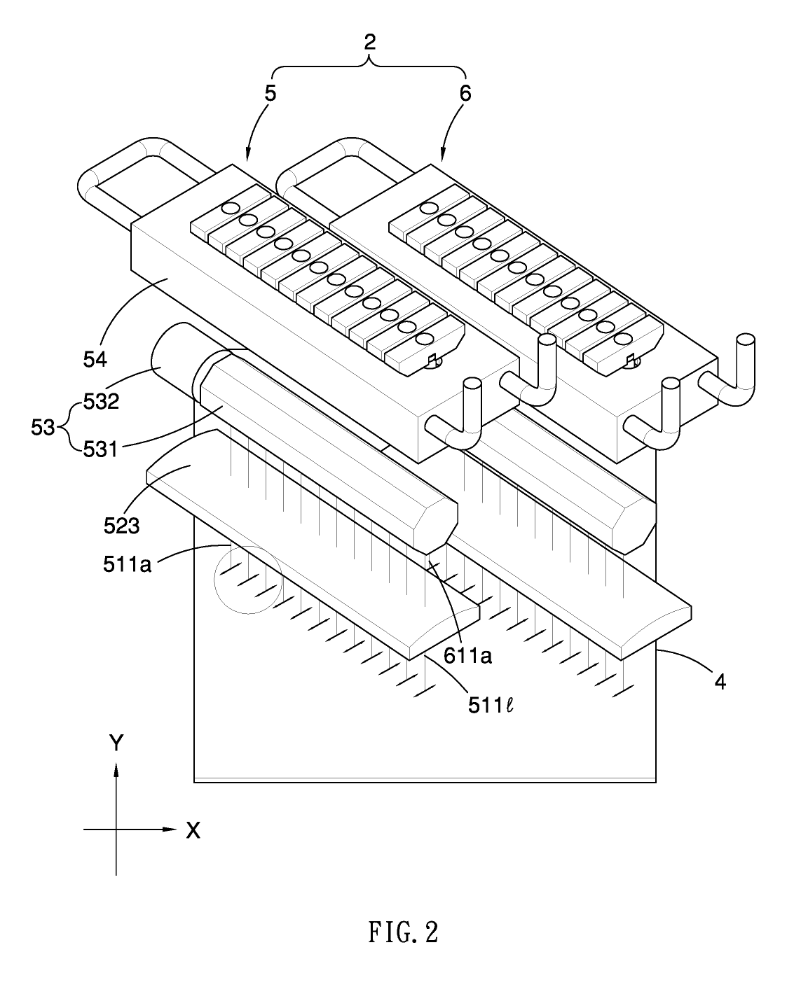

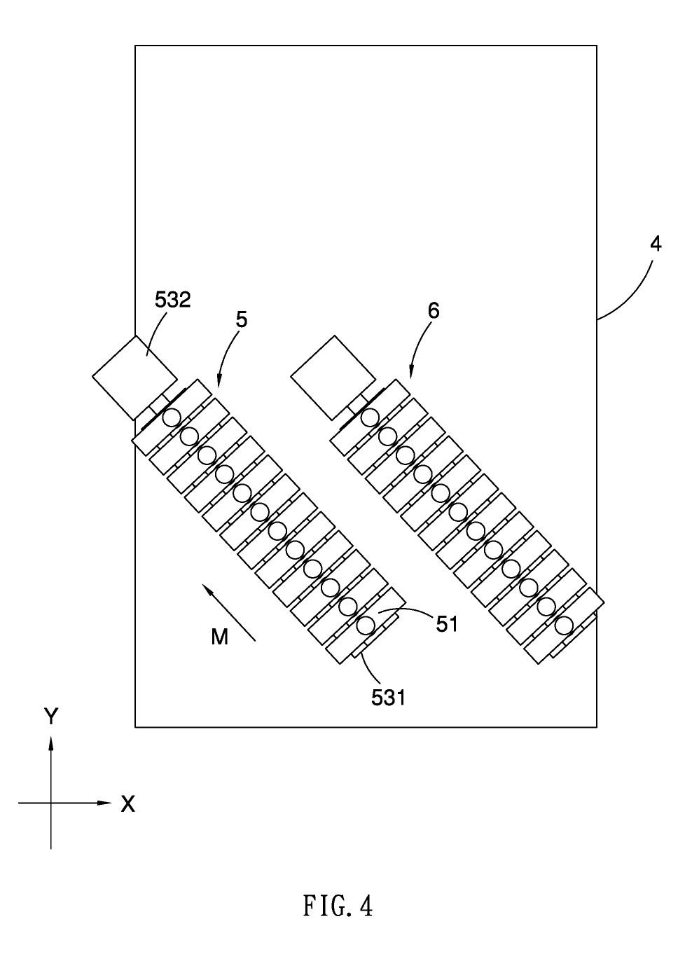

FIG. 2 shows the relative positions of the exposure device 2 and the exposed substrate 4 in FIG. 1. The exposure device 2 has a first exposure module 5 and a second exposure module 6, the structures of which are completely the same. As the plan view shown in FIG. 4, the first exposure module 5 and the second exposure module 6 are parallel each other, but incline to the displacement direction of the exposed substrate 4, which is the Y direction.

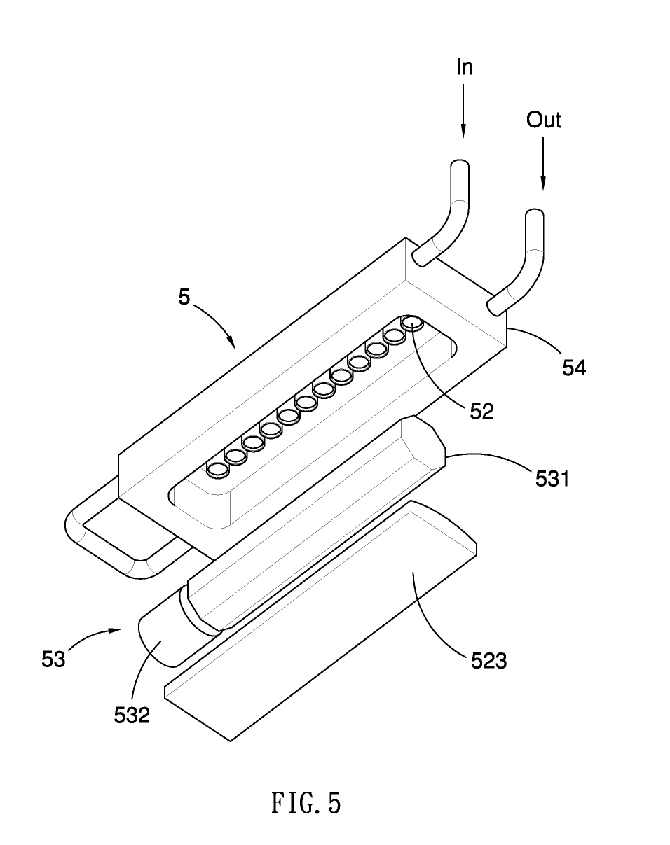

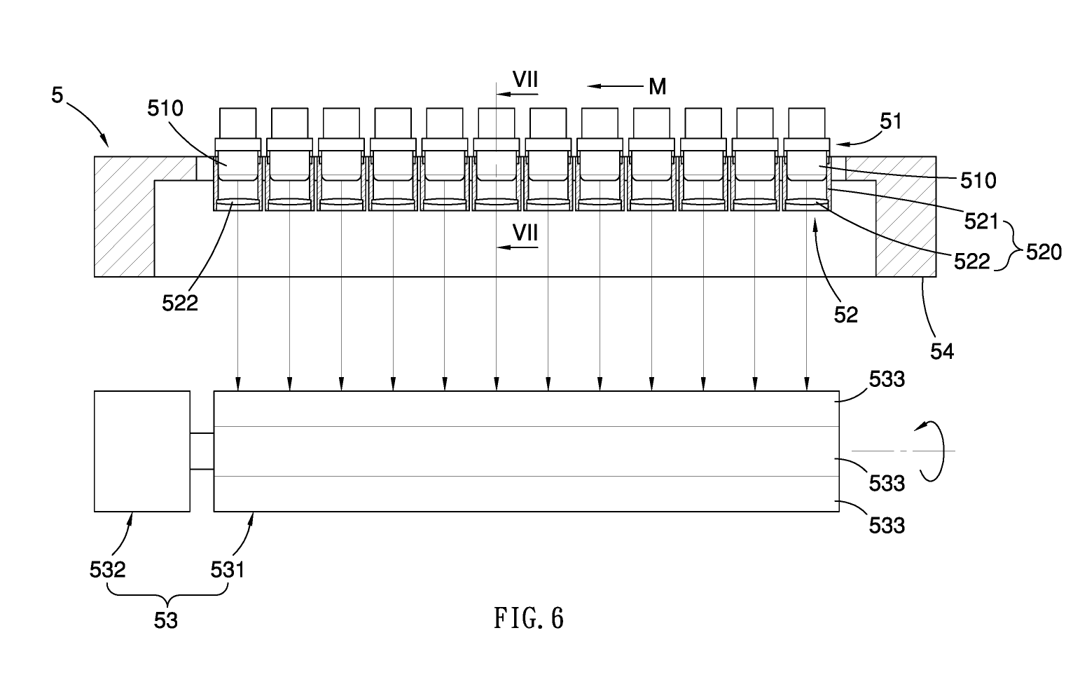

To simplify, the embodiment only takes the first exposure module 5 as an example. As shown in FIG. 5 and FIG. 6, the first exposure module 5 includes a light source 51, an optical assembly 52, a penetrating scanner 53 and a water cooling system 54. A length direction (M) of the light source 51 inclines to the X direction (as shown in FIG. 4) and includes a plurality of laser diodes 510 (better as shown in FIG. 6). The laser diodes 510 are arranged in an interval along the longitudinal direction (M) of the light source 51 to output a plurality of laser beams 511 parallel to each other. In an embodiment, the laser diodes 510 can be replaced by LEDs.

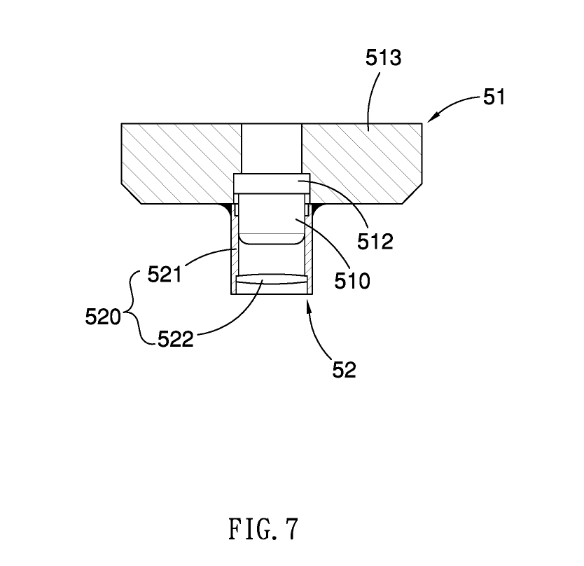

The optical assembly 52 has a plurality of focus lens unit 520 arranged along the longitudinal direction (M) of the light source 51 for separately focusing the laser beams 511 to the substrate to be exposed 4. Each focus lens unit 520 includes a lens tube 521 and a focus lens 522 disposed in the lens tube 521. The focus lens 522 prefers to use the aspherical lens molded by glass. In addition, as the lateral enlarged view shown in FIG. 7, the lens tube 521 axially sleeves in a base 51 of the laser diode 510, which is fixed in a supporting shelf 513. Furthermore, as shown in FIG. 5, the water cooling system 54 connects to the supporting shelves 513 of the light source 51 for dissipating heat from the laser diodes 510 of the light source 51 to prevent overheating that causes the laser diodes 510 to be disabled.

As shown in FIG. 6, the penetrating scanner 53 has a multifaceted prism 531 and a motor 532 for driving the multifaceted prism 531 to rotate. A rotating shaft of the multifaceted prism 531 is parallel to the longitudinal direction (M) of the light source 51. The multifaceted prism 531 has multiple facets 533, into which the laser beams 511 emit. The focus lenses 522 dispose between the light source 51 and the multifaceted prism 531.

As shown in FIG. 2 and FIG. 5, the optical assembly 52 can further include a compensated lens 523, which disposes between the multifaceted prism 531 and the exposed substrate 4 for modifying an image difference due to focusing by the focus lenses so that the laser light spots are more tiny and sharp.

The compensated lens 523 mentioned above can be implemented as a strip cylindrical lens, a whole row of spherical lenses or a whole row of aspherical lenses, wherein a diameter or a width of the compensated lens 523 is not less than a diameter of the multifaceted prism 531. In the embodiment, the compensated lens 523 is selected from the cylindrical lens, which is arranged in parallel with the prism 53. However, in other embodiment, the compensated lens 523 can be selected from a plurality of spherical lens or a plurality of aspherical lenses arranged in an interval, wherein the aspherical lens prefers to use the aspherical lens molded by glass.

As shown in FIG. 8A, the laser beam 511 emits into one of the facets 533 of the multifaceted prism 531 and emits out from another facets 533, after that, passes through the compensated lens 523 to the substrate to be exposed 4. Without the compensated lens 523, the laser beam 511 emits directly to the substrate to be exposed 4. The laser beam 511 will focus on the sensitive layer 41 of the substrate to be exposed 4 to form a light spot P.

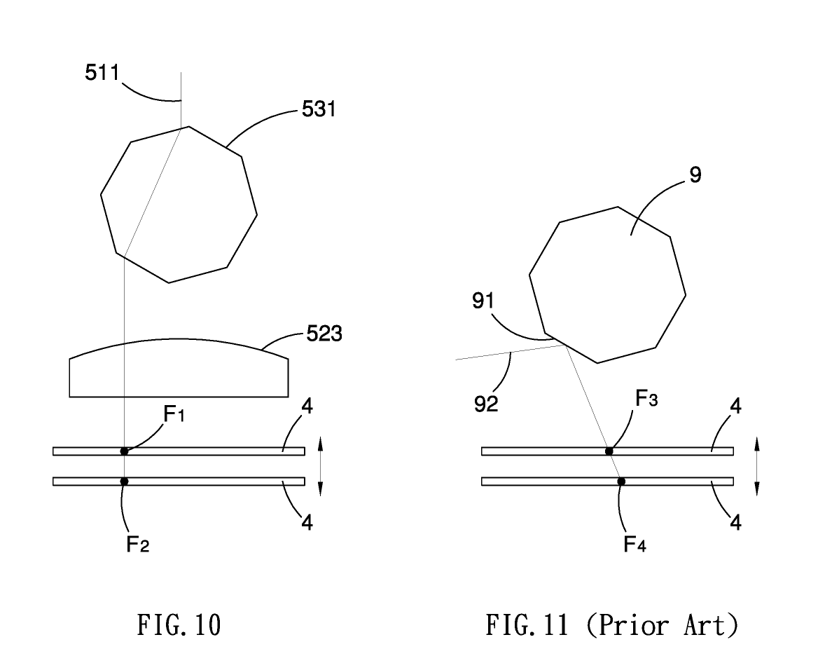

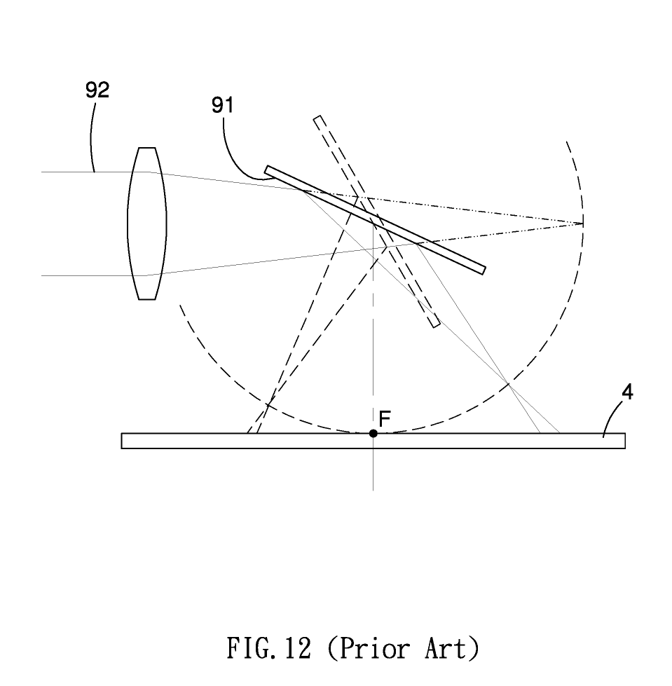

As shown in FIG. 10, after the laser beam 511 passes through the multifaceted prism 531, the height varied by the exposed substrate 4 does not shift the positions of the focus points F1, F2.

Moreover, multiple light spots P formed during the process that the multifaceted prism 531 rotates in a predetermined angle range, such as 30 degree, (refer to FIG. 8A to FIG. 8C) form a strip exposed speckle S in an inclined scanning path (N) of the sensitive layer 41 of the substrate to be exposed 4, as shown in FIG. 8C.

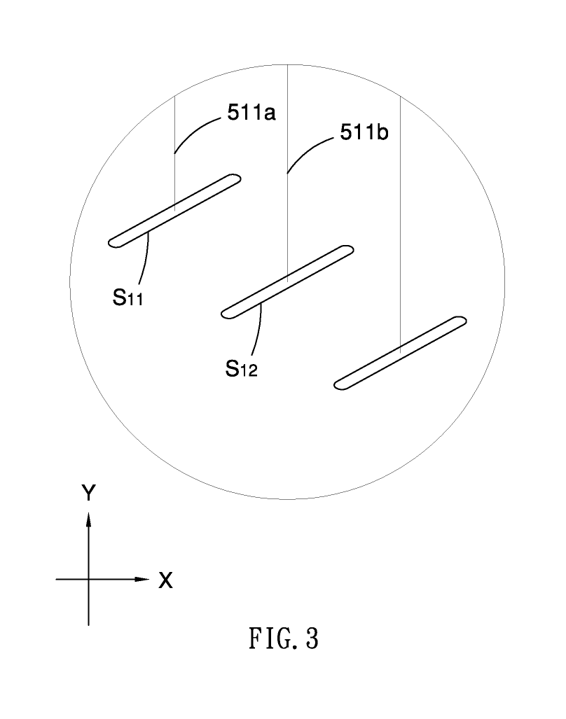

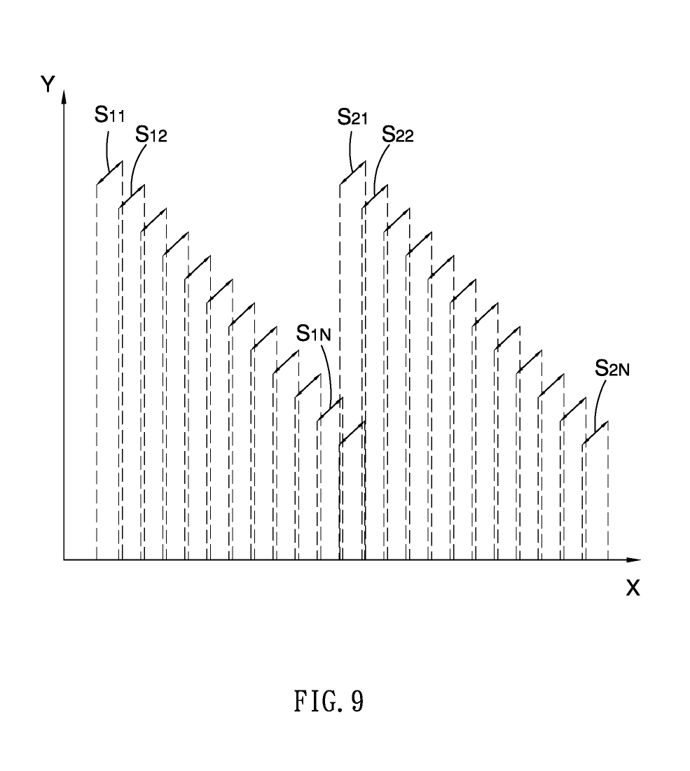

As the enlarged view shown in FIG. 3, the projections of the strip exposed speckle S11, S12 formed by the adjacent two laser beam 511a, 511b will partly overlap in the X direction. In addition, as shown in FIG. 9, the projections of the strip exposed speckle formed by the adjacent two exposed modules 5, 6 also partly overlap in the X direction. As shown in FIG. 2 and FIG. 9, the projection of the strip exposed speckle S1N formed by the last laser beam 511l of the first exposure module 5 and the projection of the strip exposed speckle S21 formed by the first laser beam 611a of the second exposure module 6 partly overlap in the X direction. Accordingly, the two exposed module 5, 6 of the exposure device 2 certainly can expose the different positions of the sensitive layer 41 of the exposed substrate 4 in the X direction. In addition, during the shifting process that the exposed substrate 4 is scanned, the control unit 3 (refer to FIG. 1) simultaneously controls the rotating of the multifaceted prism 531 and the switching of the laser diode 510 of the two exposed modules 5, 6 so that each exposed speckle or unexposed position forms a pixel of the latent image and the adjacent pixels do not form blank gaps. Preferably, the control unit 3 makes the laser beams 511 limit to emit into the facet 533 of the multifaceted prism 531 at the angle of incidence in a predetermined range, wherein the predetermined range is between the positive 20 degree angle and the negative 20 degree angle to reach the better laser light spots; more preferably, the predetermined range is between the positive 15 degree angle and the negative 15 degree angle to obtain the strip exposed speckles formed by the more meticulous laser light spots.

Take FIG. 8A to FIG. 8C for example, during the process that the multifaceted prism 531 rotates at 30 degree angle, the laser beam 511 emits into the facet 533 (refer to FIG. 8A) of the multifaceted prism 531 gradually from the initial angle of the positive 15 degree angle (+15°) to the zero degree angle of incidence, that is, perpendicularly emits into the facet 533 (refer to FIG. 8B), finally emits into the facet 533 at the angle with the negative 15 degree angle (−15°) (refer to FIG. 8C). During the process, the diameter of the laser light spots varies according to the variations of the angle of incidence.

The below table shows the laser beam emits into the facet 533 of the prism 531 at the various angles of incidence (0°˜15°) with the various types of the compensated lens 523 (including the comparison group without the compensated lens) to form the diameter of the laser light spots (unit: micrometer):

| | the types of the | the angle of incidence (degree) | | | | | |
|---|---|---|---|---|---|---|---|
| number | compensated lens | 0 | 3 | 6 | 9 | 12 | 15 |
| 1 | without | 3.60 | 4.20 | 6.20 | 8.20 | 10.30 | 12.30 |
| | compensated lens | | | | | | |
| 2 | cylindrical lens | 3.50 | 4.00 | 3.95 | 3.97 | 4.79 | 6.18 |
| 3 | spherical lens | 3.42 | 3.44 | 3.42 | 3.50 | 3.66 | 4.13 |
| 4 | aspherical lens | 1.29 | 1.33 | 1.39 | 1.61 | 1.80 | 2.03 |

As seen in the above table, in contrast to no compensated lens 523 (number 1), no matter which compensated lens 523 (number 2˜4) is added, the light spots can be reduced more or less, especially when the laser beam emits from a larger angle of incidence (such as 15 degree). Moreover, in the various types of the compensated lens 523, selecting the aspherical lens (number 4) as the compensated lens can obtain the most meticulous laser light spots, of which the diameter could be lowered down to 1 to 2 micrometer.

As mentioned above, the direct exposure machine without mask of the invention utilizes the light transmissive multifaceted prism 531 to solve the problems of focal shifting that the prior manifold reflecting mirrors of the direct exposure machine without mask.

What is claimed is:

1. A direct exposure machine without mask, comprising:
a stage device, supporting an exposed substrate, a surface of which coats with a sensitive layer; and
an exposure device, shifting relatively to the stage device and including a first exposure module, which includes:
a light source, outputting multiple beams arranged parallel each other;
a penetrating scanner, including a multifaceted prism driven to rotate, which has multiple facets, with each beam goes into one facet and out from the other to the sensitive layer of the exposed substrate; and
multi-focus lenses, disposed between the light source and the multifaceted prism for focusing the beams to the exposed substrate.

2. The direct exposure machine without mask as recited in claim 1, including a compensated lens disposed between the multifaceted prism and the exposed substrate for modifying an image difference due to focusing by the focus lens.

3. The direct exposure machine without mask as recited in claim 1, wherein the exposure device includes a second exposure module parallel to the first exposure module and the second exposure module is the same as the first exposure module.

4. The direct exposure machine without mask as recited in claim 1, wherein the first exposure module further includes a water cooling system for dissipating heat from the light source of the first exposure module.

5. The direct exposure machine without mask as recited in claim 4, wherein the exposure device includes a second exposure module parallel to the first exposure module, wherein the second exposure module is the same as the first exposure module.

6. The direct exposure machine without mask as recited in claim 1, wherein the first exposure module further includes multiple lens tubes, each of which axially sleeves in a base of a laser diode or a light emitting diode and in which the focus lens are separately disposed.

7. The direct exposure machine without mask as recited in claim 2, wherein the compensated lens includes a cylindrical lens, which is disposed in parallel with the multifaceted prism.

8. The direct exposure machine without mask as recited in claim 2, wherein the compensated lens includes multi spherical lens separately corresponding to the beam.

9. The direct exposure machine without mask as recited in claim 2, wherein the compensated lens includes multi aspherical lens molded by glass separately corresponding to the beam.

10. The direct exposure machine without mask as recited in claim 1, wherein the exposure device includes a control unit, which controls a rotating of the multifaceted prism and whether each beam of the light source is generated so that the beam is limited to emit into the facet of the multifaceted prism at the angle of incidence in a predetermined range, wherein the predetermined range is between the positive 20 degree angle and the negative 20 degree angle.
